(19) United States
(12) Patent Application Publication
(10) Pub. No.: US 2010/0061439 A1
(43) Pub. Date: Mar. 11, 2010

(54) COMMUNICATION SYSTEM, APPARATUS AND METHOD

(76) Inventors: Harold Woodruff Tomlinson, Ballston Spa, NY (US); John Anderson Fergus Ross, Niskayuna, NY (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(21) Appl. No.: 12/205,286

(22) Filed: Sep. 5, 2008

(51) Int. Cl. H03H 7/30

(52) U.S. Cl. 375/232

(57) ABSTRACT

A system and method for communication along a track implementing a channel equalizer is disclosed. The signaling system includes a track having a pair of rails spaced apart in a parallel orientation and a first signaling point electrically connected to the track. A second signaling point is electrically connected to the track and separated from the first signaling point such that the first and second signaling points are capable of communicating track data therebetween. The second signaling point includes therein a channel equalizer configured to filter the track data received from the first signaling point.

### BACKGROUND

1. Technical Field

The present disclosure includes embodiments that relate to a communication system and apparatus. The present disclosure includes embodiments that relate to a method of communication involving a channel equalizer.

2. Discussion of Art

Conventional track circuits may use signaling points to monitor a block of railroad track for the presence of trains and broken rails. Signals transmitted and/or received by the signaling points indicating the block state (e.g., whether occupied, empty, or containing a broken rail) may be used to directly control the wayside signal aspects and to send information to the train (via cab signals in the rail) or a central office (via remote communication links). The electrical current sensed at a receiving signal point may be compared to a threshold value, and decisions about track occupancy, broken rails, and bits (e.g., codes, or signal aspects) can be made based on this threshold value comparison.

High-speed communications using track circuits can be difficult because of distortion introduced by the rail inductance. This inductance, combined with current leakage between the rails, limits the communication rate to less that 10 bits-per-second (bps) over a 3 mile range. Track circuit communication has involved using different modulation approaches. These approaches may include frequency shift key, amplitude shift key, and frequency modulation. These modulation approaches may not address adequately issues of signal distortion and slow communication rates. Train detection and broken rail detection may be performed in a fixed amount of time (e.g., 1.4 seconds), it may be desired that a communications scheme for transmitting signals/bits over the track circuits be provided that allows for a relatively faster communication rate to allow more time for train and broken rail detection.

It may be desirable to have a system that can provide a faster communication rate for signals. It may be desirable to have a method for affecting signal communication rates. It may be desirable to reduce signal distortion in the transmitted signals and provide for transmission of signals over track circuits having an increased length.

### BRIEF DESCRIPTION

In accordance with one aspect of the invention, a signaling system includes a track including a pair of rails spaced apart in a parallel orientation, a first signaling point electrically connected to the track, and a second signaling point electrically connected to the track and separated from the first signaling point, the first and second signaling points capable of communicating track data therebetween. The second signaling point further includes a channel equalizer configured to filter the track data received from the first signaling point.

In accordance with one aspect of the invention, a method includes the step of feeding a modulated voltage from a transmitter to a track to generate a data packet, the data packet representing at least one of a voltage and a current. The method also includes the steps of receiving the data packet at a receiver that is electrically connected to the track, and applying the data packet to an adaptive channel equalizer in the receiver to reduce distortion in the data packet introduced by the track. The method further includes the steps of recording an amount of voltage or current represented by the data packet after application to the channel equalizer and detecting a presence of one or both of a vehicle in contact with a section of the track, and a break within the section of railroad track using the amount of voltage or current.

In accordance with one aspect of the invention, a track circuit apparatus includes a track having a first rail and a second rail, a track circuit transmitter electrically connected to the track and configured to generate a signal transmitted into the track, and a track circuit receiver electrically connected to the track and separated from the track circuit transmitter and having an adaptive channel equalizer. The track circuit receiver is configured to detect the signal, apply the detected signal to the adaptive channel equalizer, and determine a presence of one of a vehicle within a section of the track, and a break within the section of track based on one of a voltage or current level and a received signal level in the equalized signal.

Various other features will be made apparent from the following detailed description and the drawings.

### BRIEF DESCRIPTION OF THE DRAWINGS

The drawings illustrate embodiments contemplated for carrying out the invention.

In the drawings:

FIG. 1 is a schematic block diagram of an adaptive channel equalizer for use with embodiments of the invention.

FIG. 2 is a schematic block diagram of an exemplary railway communication system incorporating a channel equalizer according to an embodiment of the invention.

FIG. 3 is a flowchart illustrating a method for configuring a railway communication system according to an embodiment of the invention.

FIG. 4 is a flowchart illustrating a method for communicating data between signaling points in a railway communication system according to an embodiment of the invention.

### DETAILED DESCRIPTION

The present disclosure includes embodiments that relate to a communication system and apparatus. The present disclosure includes embodiments that relate to a method of communication involving a channel equalizer.

According to one embodiment of the invention, a signaling system includes a track including a pair of rails spaced apart in a parallel orientation, a first signaling point electrically connected to the track, and a second signaling point electrically connected to the track and separated from the first signaling point by a determined distance, the first and second signaling points capable of communicating track data therebetween. The second signaling point further includes a channel equalizer configured to filter the track data received from the first signaling point.

According to one embodiment of the invention, a method includes the step of feeding a modulated voltage from a transmitter to a track to generate a data packet, the data packet representing at least one of a voltage and a current. The method also includes the steps of receiving the data packet at a receiver that is electrically connected to the track, and applying the data packet to an adaptive channel equalizer in the receiver to reduce distortion in the data packet introduced by the track. The method further includes the steps of recording an amount of voltage or current represented by the data packet after application to the channel equalizer and detecting a presence of one or both of a vehicle in contact with a section of the track, and a break within the section of railroad track using the amount of voltage or current.

According to one embodiment of the invention, a track circuit apparatus includes a track having a first rail and a second rail, a track circuit transmitter electrically connected to the track and configured to generate a signal transmitted into the track, and a track circuit receiver electrically connected to the track and separated from the track circuit transmitter and having an adaptive channel equalizer. The track circuit receiver is configured to detect the signal, apply the detected signal to the adaptive channel equalizer, and determine a presence of one of a vehicle within a section of the track, and a break within the section of track based on one of a voltage or current level and a received signal level in the equalized signal.

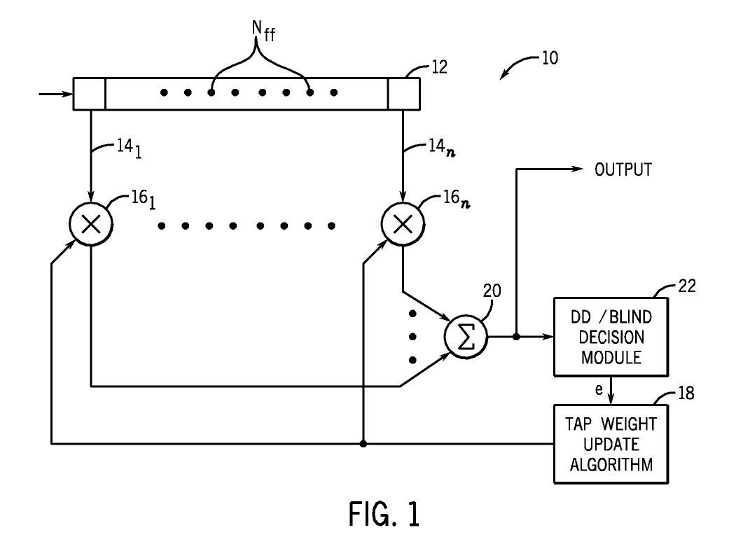

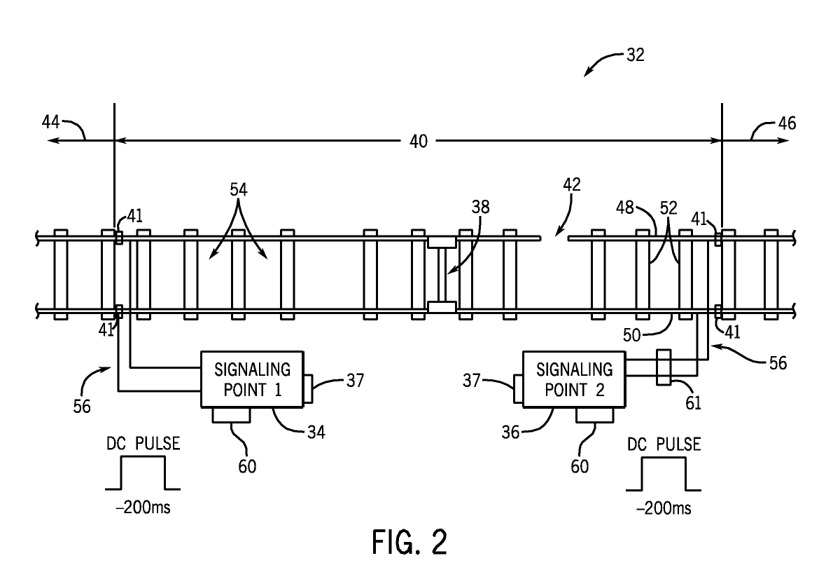

Referring to FIGS. 1 and 2, diagrams of a channel equalizer and system incorporating the channel equalizer in a signaling device for transmitting track data are shown according to embodiments of the invention. The track data can include data regarding the detection of a presence of a train or a presence of a broken rail within a predetermined section (e.g., block) of railroad track (hereinafter “track”). While FIGS. 1 and 2 show a channel equalizer and a jointed track circuit communications system incorporating the equalizer, other embodiments of the invention could also be incorporated into other forms of track circuit communications systems. That is, it is also recognized that the channel equalizer could be implemented with a jointless track circuit communications system.

Referring to FIG. 1, an adaptive channel equalizer 10 (e.g., a zero-forcing linear adaptive equalizer) that utilizes a transversal filter 12 is shown according to one embodiment of the invention. The transversal filter 12 comprises a plurality of taps N_{ff} whose weights are applied to a received signal in order to eliminate the effects of distortion from the received signal. The transversal filter 12 includes a plurality of outputs 14₁ through 14ₙ and a corresponding plurality of multipliers 16₁ through 16ₙ. The signal on each of the outputs 14₁ through 14ₙ is multiplied by a corresponding tap weight from a tap weight update algorithm 18 (such as a least mean squares (LMS)) by a corresponding one of the multipliers 16₁ through 16ₙ. The outputs from the multipliers 16₁ through 16ₙ are added together by an adder 20, and the output from the adder 20 is supplied as an output of the adaptive channel equalizer 10. The output from the adder 20 is also supplied to a decision directed/blind module 22 that compares the filter output with either a known (i.e., pre-determined) training signal when the known training signal is being received or likely corrected data decisions when unknown data instead of the known training signal is being received. This comparison forms an error signal e that is used by the tap weight update algorithm 18 to update the linear tap weights so as to minimize the value of the error e.

During training, the tap weight update algorithm 18 estimates the channel impulse response by cross-correlating the training signal as received with a stored version of the known training signal. If s[k] is defined as the stored known training sequence for k=0 . . . (L−1), and if u[k] is defined as received data sampled at the symbol rate, with u[o] being the first received training symbol in the received signal, the cross-correlation is given by the following equation:

$$h [ i ] = {\sum }_{k = 0}^{L - 1} s [ k ] u [ k + i ] , \\ for - {N}_{a} \leq i \leq {N}_{c} , \qquad [ Eqn . 1 ]$$

where N_{c} is the length of the causal response of the channel (post ghosts), and Nₐ is the length of the anti-causal channel response (pre-ghosts).

The tap weight update algorithm 18 then determines the Z-transform of h[i] and inverts the Z-transform in order to determine the tap weights that are supplied to the multipliers 16₁ through 16ₙ.

Referring now to FIG. 2, a schematic diagram is shown of the adaptive channel equalizer 10 integrated as part of a railway signaling or communication system 32 to improve data communication therein. The railway signaling system 32 includes therein first and second signaling points 34, 36 configured to communicate/transmit track data (i.e., rail signals, data packets) therebetween in one of a unidirectional and bidirectional fashion. According to one embodiment of the invention, first and second signaling points 34, 36 are in the form of a transmitter 34 and a receiver 36 and transmit/receive data by way of a communication mechanism 37. It is also recognized, however, that first and second signaling points 34, 36 could be in the form of transceivers configured to both transmit and receive track data to provide for bidirectional communication. Referring again to FIG. 2, transmitter 34 and receiver 36 are used to detect a presence of a train 38 (simply represented by a single axle and set of wheels) within a block of railroad track 40 (i.e., a track circuit). The block of railroad track 40 is defined by insulated joints 41 positioned in the track. Transmitter/receiver 34, 36 are also used to detect a broken rail 42 along railroad track block 40 and to communicate data regarding such detections therebetween. Additional blocks of railroad track 44, 46 are serially formed on either side of the block of railroad track 40, respectively. It should be noted that FIG. 2 is not drawn to scale and that the blocks of railroad track 40, 44, 46 may be of any suitable length, preferably one or more miles long.

Each block of railroad track 40, 44, 46 includes two spaced-apart parallel rails 48, 50. The metal rails 48, 50 rest on a plurality of spaced apart railroad ties 52, each of which is positioned orthogonal to the rails 48, 50. Ballast 54, such as gravel, occupies the spaces between the rails 48, 50 that are bounded on either side by the railroad ties 52. Each of the blocks of railroad track 40, 44, 46 includes a transmitter/receiver pair 34, 36 positioned between the insulated joints 41 defining the block, with pairs of connections 56 electrically connecting the transmitter/receiver 34, 36 to the rails 48, 50.

As shown in FIG. 2, transmitter 34 connects to each of the rails 48, 50. Receiver 36 for communicating with the transmitter 34 connects to each of the rails 48, 50 a desired distance/length down the rails from the transmitter within the block 40. In use, transmitter 34 provides current and/or voltage to the rails 48, 50. In one embodiment, transmitter 34 provides a keyed-on and keyed-off voltage that is amplitude modulated. The transmitter/receiver current and voltage are received and/or analyzed by the other transmitter/receiver, as further described below. As shown in FIG. 2, a voltage pulse of about 200 ms duration may be applied and may be keyed-on and keyed-off and/or have its amplitude modulated as desired by an operator. In other embodiments, different frequencies and different types of waveforms may be used, such as frequency shift key signals, amplitude shift key signals, and frequency modulated signals.

According to one embodiment of the invention, an adaptive channel equalizer 60 (such as an adaptive channel equalizer configured in the same manner as equalizer 10 in FIG. 1) is incorporated into at least one of signaling points 34, 36 (i.e., in receiver 36). In operation, adaptive channel equalizer 60 acts to improve data communication in block 40 between transmitter/receiver 34, 36. The adaptive channel equalizer 60 is employed to compensate for the effects of changing channel conditions and disturbances on the rails 48, 50. The adaptive channel equalizer 60 is configured to estimate the transfer function of the rails 48, 50 and apply the inverse of the transfer function to a transmitted/received signal so as to reduce or eliminate distortion effects. According to one embodiment of the invention, to further improve communications in communication system 32, track data filters 61 are positioned to receive data from transmitter 34 and are applied to data transferred down rails 48, 50 before the data is received by adaptive channel equalizer 60. Track data filters 61 remove (i.e., excise) narrowband amplitude and phase distortions from the received signal that result from, for example, a 60 Hz signal inductively coupled to the track (or 50 Hz signal) or a 76 Hz grade crossing frequency, along with other crossing signals and undesired interference. It is also recognized that additional designated frequencies can also be filtered out, besides those specifically set forth above. The filtered signal is then received by adaptive channel equalizer 60, which further removes amplitude and phase distortions from the received signal to thereby provide improved symbol decision capability. That is, the adaptive channel equalizer 60 removes baseband inter-symbol interference (ISI) caused by transmission channel disturbances (e.g., rail inductance) including a low pass filtering effect of the transmission channel. ISI causes the value of a given symbol to be distorted by the values of preceding and subsequent symbols. ISI represents symbol “ghosts” since ISI includes advanced and delayed symbols with respect to a reference symbol location in a given decision region.

In an exemplary embodiment, the adaptive channel equalizer 60 is configured as zero-forcing linear equalizer that acts as an adaptive digital filter (e.g., a finite impulse response (FIR) filter). The zero-forcing equalizer removes all ISI, and is ideal when the channel is noiseless. However, when the channel is noisy, the zero-forcing equalizer amplifies the noise at frequencies where the channel response has a small magnitude (i.e. near zeros of the channel) in the attempt to invert the channel completely. As such, the filter response is adapted (i.e., adapting filter coefficients/tap weights) to adequately compensate for channel distortions. While several algorithms are available for adapting the filter coefficients and thereby the filter response, in an exemplary embodiment, a least mean squares (LMS) algorithm (e.g., signed LMS algorithm) is employed. In this algorithm, by varying coefficient values as a function of a representative error signal, the equalizer output signal is forced to approximate a reference data sequence. This error signal is formed by subtracting the equalizer output signal from the reference data sequence. As the error signal approaches zero, the adaptive channel equalizer 60 approaches convergence, whereby the equalizer output signal and the reference data sequence are approximately equal.

As set forth above with respect to FIG. 1, when the operation of adaptive channel equalizer 60 is initiated, the coefficient values (filter tap weights) are usually not set at values which produce adequate compensation of channel distortions. Thus, in an exemplary embodiment, a known “training” signal is used as the reference signal in order to force initial convergence of the equalizer coefficients. Training signals are programmed at transmitter 34. An error signal is formed at receiver 36 by subtracting a locally generated receiver copy of the training signal from the output of the adaptive equalizer 60. The training signal helps to open the initially occluded “eye” characteristic of the received signal.

After adaptation with the training signal, the “eye” has opened considerably and the adaptive equalizer 60 is switched to a decision-directed operating mode. In this mode, final convergence of the filter tap weights is achieved by using the actual values of symbols from the output of the equalizer 60 instead of using the training signal. That is, when acting in decision-directed mode, adaptive equalizer 60 receives track data and automatically adapts to any changes in the rails 48, 50, such as a change in inductance. The decision-directed equalizing mode allows for the tracking and cancelling of time varying channel distortions in the rails 48, 50 more rapidly than were periodically transmitted training signals continually sent.

While channel equalizer 60 is described above as an adaptive channel equalizer, according to another embodiment of the invention, it is also recognized that the channel equalizer could have fixed coefficient values/filter tap weights through the duration of its operation. That is, upon an initial convergence of the equalizer coefficients by way of the training signals, the coefficients would be set in channel equalizer 60. In such an embodiment, channel equalizer 60 would not adapt to changes in the rails 48, 50, but maintain its fixed coefficient values/filter tap weights and operate to cancel channel distortions in a constant manner.

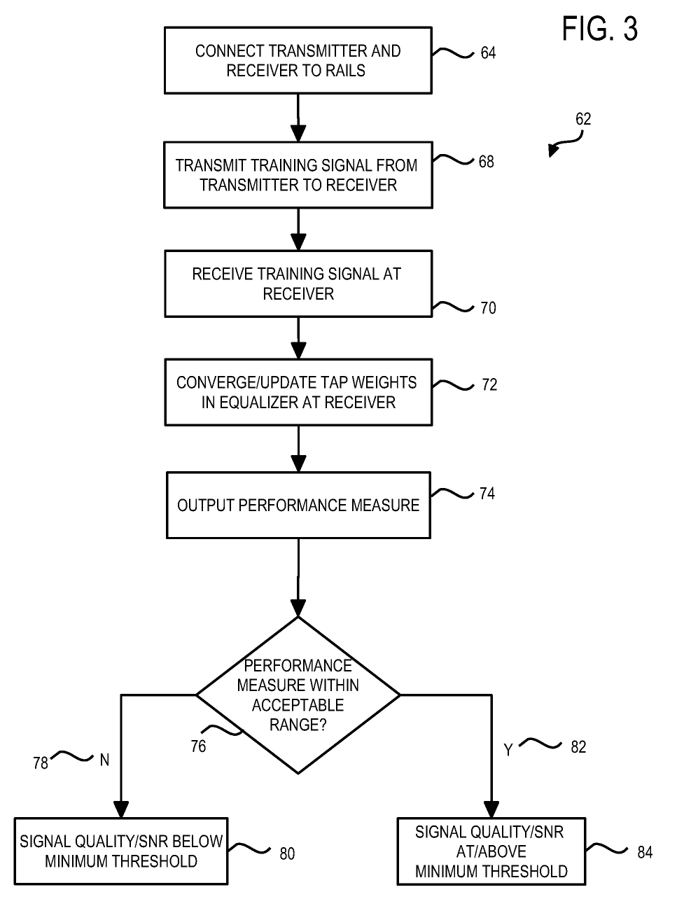

Referring now to FIG. 3 (and with continued reference to FIG. 2), a technique 62 is shown for configuring the channel equalizer 60 and for determining a sufficient signal quality for the railway signaling system 32 of FIG. 2. According to an embodiment of the invention, transmitter/receiver 34, 36 are connected to rails 48, 50 by way of connections 56 at STEP 64 near insulating joints 41 that define a track circuit or block 40. After connection, a known (i.e., pre-determined) training signal is transmitted from transmitter 34 at STEP 68. The training signal is received by receiver 36 at STEP 70 and is used as the reference signal in order to force initial convergence of the tap weights in the channel equalizer 60 of receiver 36. An error signal is formed at receiver 36 by subtracting a locally generated receiver copy of the training signal from the output of the equalizer 60 of receiver 36. The error signal is used by a tap weight update algorithm (e.g., least mean squares (LMS)) to update the linear tap weights at STEP 72, so as to minimize the value of the error (i.e., minimized mean square error). Based on the minimized mean square error, the receiver 36 is configured to output a performance measure at STEP 74 that is indicative of the quality (such as the signal-to-noise (SNR) ratio) of the received signal (i.e., the value of the error). The performance measure can, in one embodiment, quantify a bit error rate, frame error rate or checksum, for example, which can be output in the form of a numerical indicator, (e.g., a value between 1 and 100), that is displayed to an installer and which is indicative of the error value. Alternatively, in another embodiment, it is envisioned that the performance measure could be output via red-yellow-green indicator lights that indicate if an error value of the equalizer output is within an acceptable level. Based on the performance measure that is output, a determination is made at STEP 76 as to whether the performance measure is within an acceptable or desired range. If it is not 78, then it is determined at STEP 80 that the quality/SNR of the signal is below a minimum threshold the length of the track circuit/block 40 is too great. The length of the block 40 can thus be adjusted by repositioning one or both of the insulating joints 41. If the performance measure is within an acceptable or desired range 82, then it is determined at STEP 84 that the quality/SNR of the signal is above a minimum threshold.

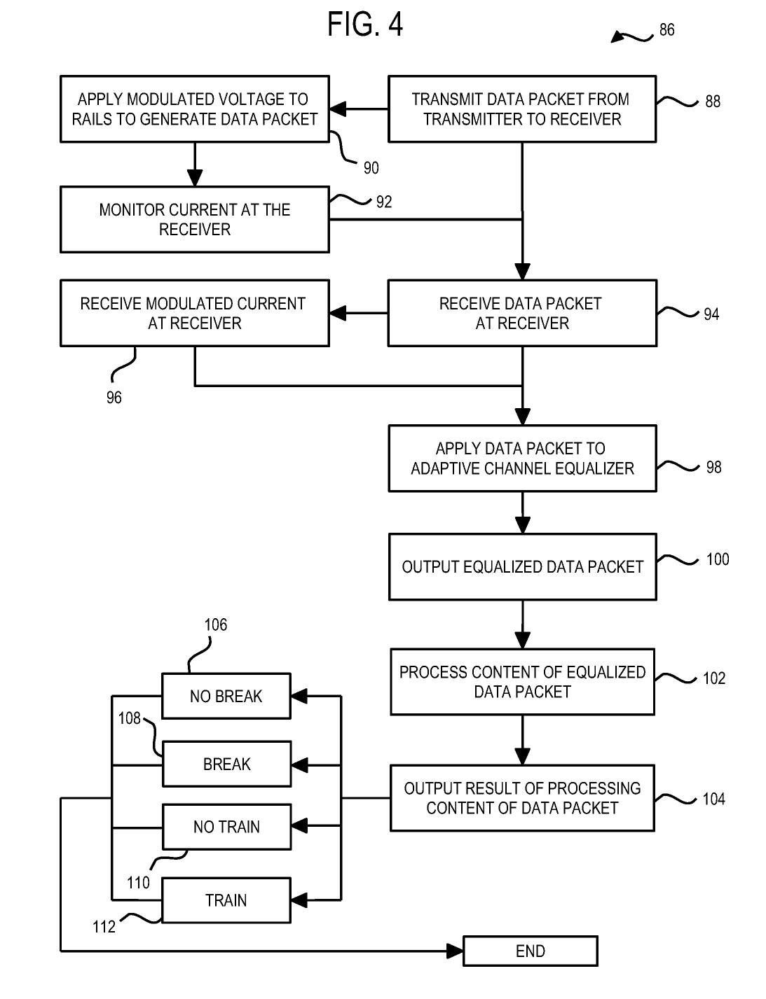

According to one embodiment of the invention, upon a determination that the length of block 40 allows for an acceptable SNR of the received signal, the channel equalizer 60 in receiver 36 enters a decision-directed mode to adapt to any changes in the rails 48, 50 during communication of track data between the signaling points, thus providing an adaptive channel equalization. Referring now to FIG. 4, a flowchart of an exemplary technique 86 for communicating data to and from transmitter/receiver 34, 36 is shown. Referring to FIGS. 2 and 4, the technique 86 may begin at STEP 88 by sending a data packet (representing at least one of a voltage and a current) from transmitter 34 to receiver 36. The STEP 88 may include STEPS 90 and 92. At STEP 90, modulated voltage (e.g., DC voltage) applied to the rails 48, 50 from the transmitter 34 creates the data packet. At STEP 92, in response to the modulated voltage provided by transmitter 34, voltage or current is monitored at receiver 36.

As the transmitter 34 sends the data packet to the receiver 36, the technique 86 may further include a STEP 94 of receiving the data packet at the receiver 36. The STEP 94 may include STEP 96, at which the receiver 36 receives the modulated current provided by the transmitter 34, although it is recognized that voltage could also be received. It is recognized that the data rate of rail communication is slow (˜10 bps) and that an exact time at which a data packet is received by second signaling point 36 may be uncertain. Thus, according to one embodiment, receiver 36 samples the track data for a duration of a sampling window at STEP 94 (i.e., oversamples) so as to receive the transmitted data packet.

At STEP 98, the data packet sampled during the sampling window is applied to the adaptive channel equalizer 60 of receiver 36. Channel equalizer 60 in receiver 36 then equalizes the data packet received during the sampling window over the range of time offsets. A least mean squares value of the equalized track data obtained over the sampling window is estimated and is output at STEP 100 as an equalized data packet whose voltage or current level is recorded. At STEP 102, the content of the equalized data packet (i.e., current level) may be processed by a control device and/or compared with a data structure to determine one or more characteristics about a predetermined block of railroad track 40, such as the presence of a train in the block(s) or a break in the track in the block(s). That is, current and/or voltage detected by second signaling point 36 is compared with predetermined combinations of current/voltage that represent different situations. Such situations may include, for example: No-Train, Train, No Break, and Break.

At STEP 104, a result of processing the content of the data packet is outputted. STEP 104 may include a STEP 106 of outputting a result of “NO BREAK,” meaning that a block of railroad track 40, 44, 46 has no breaks. Alternatively, STEP 104 may include a STEP 108 of outputting a result of “BREAK,” meaning that a block of railroad track 40, 44, 46 has a break in one or both of its section of rails. STEP 104 may further include a STEP 110 of outputting a result of “NO TRAIN,” meaning that no train is present within a block of railroad track 40, 44, 46. Alternatively, STEP 104 may further include a STEP 112 of outputting a result of “TRAIN,” meaning that a train has been detected within a block of railroad track 40, 44, 46. After all results have been outputted, the technique 86 may end.

It is recognized that equalization of track data (i.e., data packets) transmitted along rails 48, 50 reduces distortion in the received data packets. Separate filters can be included in communication system 32 to filter out unwanted narrowband noise before the transmitted track data is received by the channel equalizer 60, such as 60 Hz noise inductively coupled into the track and/or grade crossing frequencies/noise. Additionally, other non-information carrying signals present in rails 48, 50 that are amenable to cancellation may also be removed by the adaptive channel equalizer 60. Equalization of the track data thus allows for a higher data communication/transmission rate to be achieved in the track circuit, such as speeds of around 100 bps. Additionally, equalization of the track data also allows for the track circuit/block length 40 (i.e., distance between insulating joints 41 and between transmitter/receiver 34, 36) to be increased and/or for poorer ballast 54 conditions, while still maintaining an acceptable signal quality. Increases in track circuit length can, for example, be approximately 1.5 times to 2 times farther than the typical distance (e.g., 2.5 miles) that separates signaling points today.

As set forth above, the channel equalizer 60 beneficially reduces distortion in track data transmitted along rails 48, 50. During a training or installation period of the channel equalizer 60, tap weights of the equalizer are determined and a performance measure is generated based on an error signal of the equalizer output. The performance measure is indicative of an acceptable circuit length in the railway signaling system. According to one embodiment of the invention, upon an initial configuring of the tap weights in the channel equalizer 60, the equalizer enters into a decision-directed mode to adapt to any changes in the rails 48, 50 during communication of track data between the transmitter/receiver 34, 36, thus providing an adaptive equalizer that allows for the cancellation of noise sources in the rails and for the reducing of distortion in the track data.

Embodiments of the adaptive equalization methods and system described herein are configured to co-exist with existing signaling systems. Consequently, signals to and from the signaling points are designed not to interfere with grade crossing and cab signals For example, embodiments of the invention can be implemented with various jointless track circuit systems, such as those employing passive signaling devices therein.

The invention has been described in terms of exemplary embodiments, and equivalents, alternatives, and modifications, aside from those expressly stated, are possible and within the scope of the appending claims.

What is claimed is:

1. A signaling system, comprising:
a track including a pair of rails spaced apart in a parallel orientation;
a first signaling point electrically connected to the track;
a second signaling point electrically connected to the track and separated from the first signaling point;
wherein the first and second signaling points are capable of communicating track data therebetween; and
wherein the second signaling point comprises a channel equalizer configured to filter the track data received from the first signaling point.

2. The signaling system of claim 1, wherein the channel equalizer comprises a plurality of filter tap weights and is configured to set values of the plurality of filter tap weights by way of a training signal.

3. The signaling system of claim 2, wherein the channel equalizer comprises an adaptive channel equalizer configured to adjust the values of the plurality of filter tap weights.

4. The signaling system of claim 3, wherein the adaptive channel equalizer is configured to operate in a decision-directed mode to adjust to changes in a condition of the track.

5. The signaling system of claim 3, wherein the adaptive channel equalizer comprises a zero-forcing adaptive channel equalizer.

6. The signaling system of claim 2, wherein the channel equalizer is configured to:
output a performance measure based on the set values of the filter tap weights; and
determine if a signal-to-noise ratio of the track data exceeds a minimum threshold based on the performance measure.

7. The signaling system of claim 6, wherein the performance measure comprises one of a bit error rate, a frame error rate, and a checksum value.

8. The signaling system of claim 1, wherein the track data comprises at least one of voltage data and current data at at least one of the first signaling point and the second signaling point.

9. The signaling system of claim 1, wherein the second signaling point is configured to:
sample the track data for a duration of a sampling window;
equalize the track data sampled during the sampling window; and
estimate a least mean squares value of the equalized track data.

10. The signaling system of claim 1, further comprising a track data filter positioned to receive the track data from the first signaling point and filter out noise from the track data.

11. The signaling system of claim 10, wherein the track data filter is configured to filter out a 60 Hz noise signal.

12. The signaling system of claim 1, wherein the second signaling point is configured to detect at least one of a vehicle within a block of track, and a break in a respective rail of the pair of rails in the block of track within the determined distance.

13. The signaling system of claim 1, wherein the first signaling point is configured to key-on and key-off a voltage signal applied to the railroad track.

14. The signaling system of claim 13, wherein the first signaling point is further configured to modulate an amplitude of the voltage signal.

15. A method, comprising:
feeding a modulated voltage from a transmitter to a track to generate a data packet, the data packet representing at least one of a voltage and a current;
receiving the data packet at a receiver that is electrically connected to the track;
applying the data packet to an adaptive channel equalizer in the receiver to reduce distortion in the data packet introduced by the track;
recording an amount of voltage or current represented by the data packet after application to the channel equalizer; and
detecting a presence of one or both of a vehicle in contact with a section of the track, and a break within the section of railroad track using the amount of voltage or current.

16. The method of claim 15, further comprising:
applying a training signal to the adaptive channel equalizer to determine coefficient values in the adaptive channel equalizer; and
outputting a performance measure from the adaptive channel equalizer based on the determined coefficient values.

17. The method of claim 16, further comprising determining if a signal-to-noise ratio of the data packet exceeds a minimum threshold based on the performance measure.

18. The method of claim 15, wherein receiving the data packet at the second signaling point comprises receiving a plurality of data packets over a duration of a sampling window; and
wherein applying the data packet to the adaptive channel equalizer comprises equalizing the plurality of data packs received over the duration of the sampling window and estimating a least mean squares value of the equalized data packets.

19. The method of claim 15, wherein feeding the voltage from the first signaling point to the railroad track comprises feeding an amplitude modulated voltage to the railroad track.

20. A track circuit apparatus comprising:
a track including a first rail and a second rail;
a track circuit transmitter electrically connected to the track and configured to generate a signal transmitted into the track; and
a track circuit receiver electrically connected to the track and separated from the track circuit transmitter and comprising an adaptive channel equalizer, the track circuit receiver configured to:
detect the signal;
apply the detected signal to the adaptive channel equalizer; and
determine a presence of one of a vehicle within a section of the track, and a break within the section of track based on one of a voltage or current level and a received signal level in the equalized signal.

21. The track circuit apparatus of claim 20, wherein the adaptive channel equalizer is further configured to operate in an installation mode and a decision-directed mode.

22. The track circuit apparatus of claim 21, wherein when operating in the installation mode, the adaptive channel equalizer is further configured to:
set an initial value for filter tap weights in response to received training signals;
generate an equalizer output in response to the training signals; and
determine a performance measure based on the equalizer output.

23. The track circuit apparatus of claim 22, wherein the adaptive channel equalizer is further configured to determine if a signal-to-noise ratio of the signal exceeds a minimum threshold based on the performance measure.

24. The track circuit apparatus of claim 21, wherein when operating in the decision-directed mode, the adaptive channel equalizer is further configured to adjust a value for filter tap weights in real-time based on one or more changes in track conditions.

25. The track circuit apparatus of claim 20, wherein the adaptive channel equalizer is further configured to:
sample the signal for a duration of a sampling window;
equalize the signal sampled during the sampling window; and
estimate a least mean squares value of the equalized signal.
